(19) United States
(12) Patent Application Publication
(10) Pub. No.: US 2014/0339920 A1
(43) Pub. Date: Nov. 20, 2014

(54) Thermal Runaway and Fire Detection and Prevention Device

(71) Applicants: Robert E. Ingalls, JR., Lafayette, CA (US); Douglas E. Frazier, Claremont, CA (US); Michael Xavier, Aurora, CO (US)

(72) Inventors: Robert E. Ingalls, JR., Lafayette, CA (US); Douglas E. Frazier, Claremont, CA (US); Michael Xavier, Aurora, CO (US)

(21) Appl. No.: 13/894,413

(22) Filed: May 14, 2013

(51) Int. Cl. G01R 31/36

(52) U.S. Cl. CPC G01R 31/3606
USPC 307/125; 324/426; 324/433

(57) ABSTRACT

A system and method to monitor and control a battery string in an uninterruptible power supply unit is provided. The present system and method aids in the prevention of thermal runaway conditions which may lead to battery damage and fire. Battery parameters are measured and compared to a given standard to determine if the measured parameter deviates from a range of acceptable standard range. A time delay is initiated if the measured parameter is outside the acceptable standard range and the battery parameter is remeasured. If the measured parameter is still outside the acceptable standard range, than an alarm is activated, which may include disconnecting the battery string from the charger and producing a perceptible alarm. False alarms are reduced and true runaway scenarios can be prevented at an early stage with the present system and method.

### RELATED APPLICATION DATA

This application claims the priority date of provisional application No. 61/646,622 filed on May 14, 2012.

### BACKGROUND

The present system and method relates to a thermal runaway and fire detection and prevention device for batteries within an uninterruptable power supplies or similar battery backup system.

There are numerous strings of valve-regulated lead acid (VRLA) batteries and other battery types in services that function as power backups in case of an AC power outage. The VRLA battery systems are often installed as part of an uninterruptable power supply (UPS) system, within telecommunication systems, or in other similar applications that require constant power reliability. The owners and maintainers of the VRLA systems frequently do not properly maintain these systems and may forget they even exist, as they are often hidden in power closets and cabinets. Because of this neglect, many batteries in a VRLA system remain in service well beyond their design lives or after cells within the string have shorted.

Charge in VRLA systems is maintained by float charging the string, where a continuous voltage is applied to the battery terminals. Depending on the battery manufacturer's recommendations, the batteries are charged at a voltage level that is a set amount above the open cell voltage of the battery when it is fully charged (perhaps 0.08-0.13 V above open cell voltage) to compensate for self-discharge. Thus, when the battery string is called into service, there will be sufficient charge for the battery to deliver its full charge capacity. However, it is important to properly regulate the float voltage and float current to prevent damage to the battery, overcharging, undercharging, or overheating.

During float charging, a small amount of heat is generated even in well maintained VRLA batteries due to resistance to current flow through the cells. When VRLA systems are not well maintained and as they age, there is a risk of thermal runaway, where the batteries cannot adequately dissipate the heat generated during charging. Essentially, aging or damaged batteries require a higher float current due to a large portion of the float current supporting the recombination of oxygen at the negative plate, which is an exothermic reaction that generates excess heat. The generated heat from the increased float current causes the battery temperature to rise. In turn, as the battery temperature increases, the float current and float voltage will also increase, where the float current doubles for a temperature increase of approximately 15-18° F. In this manner, a hazardous cycle of float current increases and temperature increases will slowly evolve into a thermal runaway condition. Once a critical point is reached, the battery is no longer able to dissipate the heat causing a fire hazard.

Following a deep discharge scenario, where the battery has been utilized in a power outage to the point where close to 100% of the battery has been discharged, the charging system must provide current well above the float current, usually running at the maximum safe level until the battery voltage rises to about 80-90% of full charge level. When charging the batteries at such a high current, the risk of thermal runaway yet again increases. Quick action must be taken to prevent damage or fire.

The initial signs of thermal runaway are often difficult to detect and slow to develop, but can quickly accelerate to a dangerous condition if left unchecked. Many monitoring systems measure float voltage, battery temperature, and float current in the attempt to prevent thermal runaway. However, existing systems tend to generate excessive and undesirable false alarms by mere measurement of these conditions.

Both the International Code Counsel and the National Fire Protection Association have recommended identical model codes (2009 IFC 608 and NFPA 1, Article 52), which state that “VRLA . . . battery systems shall be provided with a listed device or other approved method to preclude, detect and control thermal runaway.” Thus, there is an industry-wide recognized need for thermal runaway detection and prevention systems, both for battery protection and public safety. These systems should not generate excessive false alarms, yet should be able to detect a true thermal runaway scenario at an early stage, where preventive measures can be easily implemented to prevent hazardous conditions and damage to the UPS system.

### SUMMARY

The present system and method provide an effective battery monitor and controller that detects hazardous conditions before substantial damage, while preventing false alarms. The present system can detect true thermal runaway conditions at an early stage, such that preventative measures can be taken. Yet, the present system avoids unnecessary disconnections and maintenance calls, saving resources and keeping the battery system charging and operational.

A method to monitor and control a battery string charged by a charging source and connected to a critical load is provided. First, a battery parameter is measured with a sensor to collect a measurement indicative of the condition of the battery string. The battery parameters can include at least a float current, a float voltage, a battery temperature, a hydrogen level, a smoke particulate level, and a heat level. The sensor is any appropriate means to measure a desired parameter, including temperature sensors (such as thermometers, thermocouples, thermistors, and the like), current sensors (such as hall effect sensors, galvanometer, and the like), voltage sensors (such as voltmeters and the like), hydrogen sensor (such as electrochemical hydrogen sensors, MEMS hydrogen sensor, thick/thin film sensors, and the like), smoke detectors (such as optical smoke detectors, ionization smoke detectors, carbon monoxide/dioxide sensors, particulate air-sampling sensors, and the like), and heat sensors (such as fixed temperature detectors, rate-of-rise heat detectors, and the like).

Second, the measurement is compared with a standard battery parameter. The standard battery parameter is often a user-selected value or manufacturer recommended value for operational temperature, float voltage at a given temperature, and float current at a given temperature and float voltage. The user may also enter values based on industry experience and recommended values from safety organizations, such as OSHA.

Third, it is determined whether the measurement deviates outside a set range from the standard battery parameter. The range, for example the float voltage, may be set by the user or battery manufacturer and expressed as a percentage or quantity above and below the recommended standard battery parameter (such as ±0.3V).

Fourth, if the measurement deviates outside the set range from the standard battery parameter, a time delay is initiated. The time delay should be sufficient to permit a temporary deviation or outlying quantity to correct itself without intervention. These temporary deviations may be caused by a particularly hot day, or other factors that may cause a deviation, but will not ultimately lead to a thermal runaway scenario or other dangerous condition. Basically, the time delay prevents many false alarms. The time delay may range from several hours or less to one or more days.

Fifth, at least once during the time delay the battery parameter is remeasured to collect an additional measurement. The additional measurement is a recheck of the measurement. The additional measurement may be taken just once, several times during the time delay, or taken on a continuous basis throughout the time delay. For example, a measurement may be taken once every second.

Finally, if the additional measurement deviates outside the set range from the standard battery parameter, an alarm is activated. The alarm may be a visual alarm, such as a LED light, that is labeled to communicate the nature of the alarm (such as a “check” light, a “fire pending” light, or the like). The alarm may be an audible alarm, such as a buzzer, bell, or the like. Further, the alarm may be communicated to a remote user or computer by wired or wireless means. If it is determined a condition warrants immediate action, the battery string may be disconnected from the charging source as part of an alarm activation.

The step of measuring the battery parameter may include measuring a float voltage and comparing the float voltage with a standard float voltage that has been compensated for a measured battery temperature. The step of measuring the battery parameter may include measuring a float current and comparing the float current with a standard float current that has been compensated for a measured battery temperature and that has been compensated for a measured float voltage.

After disconnecting the battery string, the method may include the further steps of initiating a disconnect time delay and reconnecting the battery string to the charging source after expiration of the disconnect time delay. This delay is useful in scenarios such as when the battery temperature has increased to an unsafe level due to bulk charging. Disconnecting the charging source immediately eliminates the major source of heat and permits the batteries to cool until reaching a safe level.

After reconnecting the battery string to the charging source, the method can include the further steps of measuring the battery parameter to collect a verification measurement. Next, the verification measurement is compared with the standard battery parameter. Then, it is determined whether the verification measurement deviates outside the set range from the standard battery parameter. Next, a second time delay is initiated, if the measurement deviates outside the set range from the standard battery parameter. Then, the battery parameter is measured at least once during the second time delay to collect a further additional measurement. And, the alarm is activated if the further additional measurement deviates outside the set range from the standard battery parameter.

The method may further include the steps of disconnecting the battery string from a charging source by opening a contactor arranged in parallel with a diode, wherein the battery string is normally connected to the charging source through the contactor and the diode. Then the current through the diode is measured continuously or periodically. Next, the contactor is maintained in the open position, if no current is detected through the diode. Finally, if a current is detected through the diode, the contactor is closed. In this way, the battery string can be immediately reconnected to the critical load in the event of a power failure.

The step of determining whether the measurement deviates outside the set range from the standard battery parameter may include determining whether the measurement deviates outside a first set range from the standard battery parameter. It is also determined whether the measurement deviates outside a second set range from the standard battery parameter, wherein the second set range is greater than the first set range. A perceptible alarm (visual or audible) is produced if the measurement deviates outside the first set range and is within the second set range. If the measurement deviates outside the second set range, the battery string is disconnected from a charging source. In this way, if the measurement is only slightly high or low, an appropriate warning can be issued, such as a yellow light or the like. If the measurement is substantially high or low, and this poses an immediate threat, then immediate action can be taken or a higher level alarm can be activated.

The step of measuring the battery parameter may include measuring a hydrogen level. The step of comparing the measurement with the standard battery parameter may include comparing the hydrogen level with a maximum hydrogen level. The step of measuring the battery parameter with the sensor may include measuring the battery parameter with a smoke detection device. The step of measuring the battery parameter may include measuring a smoke particulate level with the smoke detection device. The step of comparing the measurement with the standard battery parameter may include comparing the smoke particulate level with a maximum smoke particulate level, wherein the maximum heat level is deemed exceeded when the heat detection device activates.

The step of measuring the battery parameter with the sensor may include the step of measuring the battery parameter with a heat detection device. The step of measuring the battery parameter may include measuring a heat level with the heat detection device. The step of comparing the measurement with the standard battery parameter may include comparing the heat level with a maximum heat level, wherein the maximum heat level is deemed exceeded when the heat detection device activates.

### BRIEF DESCRIPTION OF THE SEVERAL VIEWS OF THE DRAWINGS

FIG. 1 is a diagram of the present battery monitoring system, showing the diode and the contactor within the charge inhibitor unit and the current and temperature probes;

FIG. 2 is a logic diagram of the dynamic battery monitor relay;

FIG. 3 is a flow chart describing the present method;

FIG. 4 is a flow chart describing an alternate embodiment of the present method;

FIG. 5 is a flow chart describing an alternate embodiment of the present method; and

FIG. 6 is a flow chart describing an alternate embodiment of the present method;

### LISTING OF REFERENCE NUMERALS OF FIRST-PREFERRED EMBODIMENT

battery monitoring system 20
battery string 22
second battery string 24
ambient temperature probe 26
diode 28
second diode 30
current sensor 32
second current sensor 34
contactor 36
second contactor 38
distribution module 40
perceptible alarm 44
charge inhibitor unit 46
second charge inhibitor unit 48
positive bus 50
negative bus 52
battery temperature probe 54
second battery temperature probe 56

### DESCRIPTION OF THE PREFERRED EMBODIMENTS

The detailed descriptions set forth below in connection with the appended drawings are intended as a description of embodiments of the invention, and is not intended to represent the only forms in which the present invention may be constructed and/or utilized. The descriptions set forth the structure and the sequence of steps for constructing and operating the invention in connection with the illustrated embodiments. It is to be understood, however, that the same or equivalent structures and steps may be accomplished by different embodiments that are also intended to be encompassed within the spirit and scope of the invention.

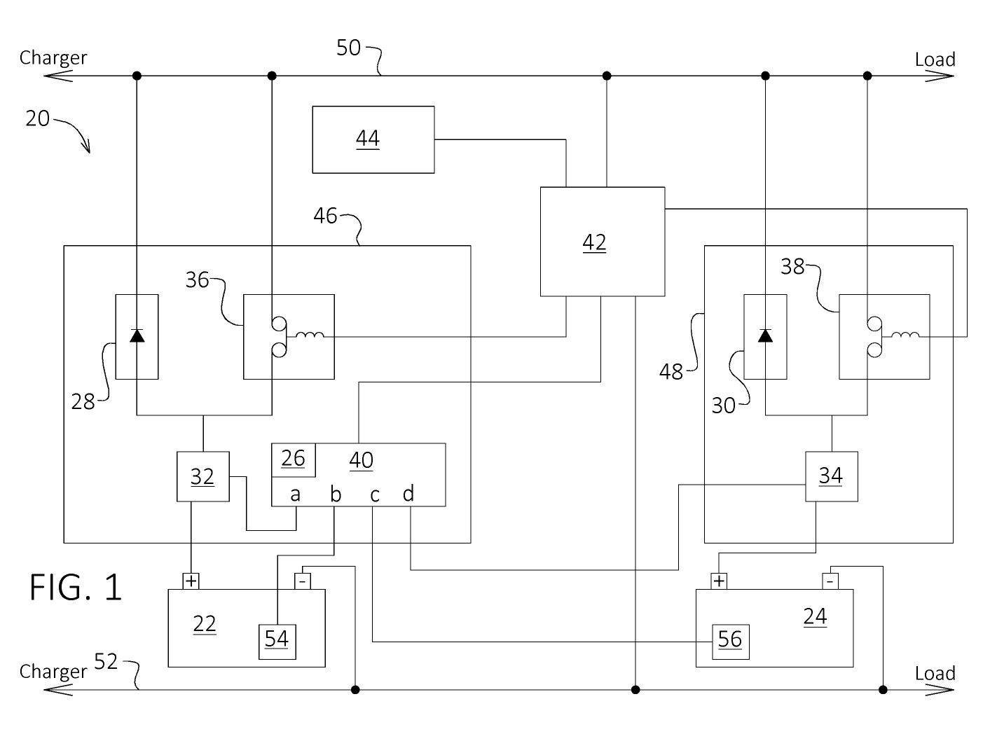

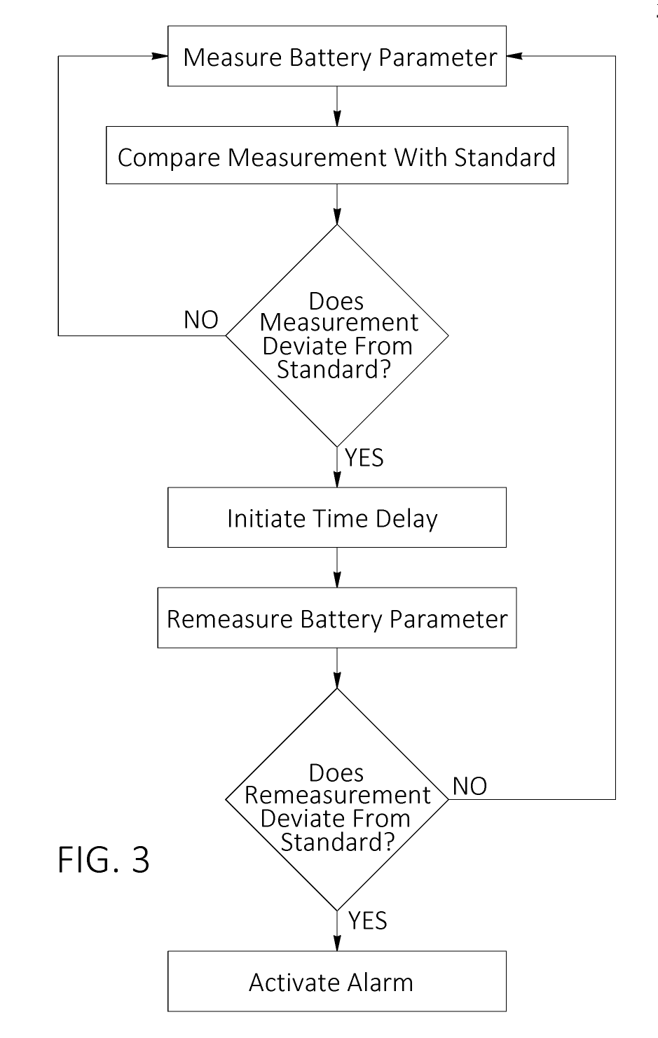

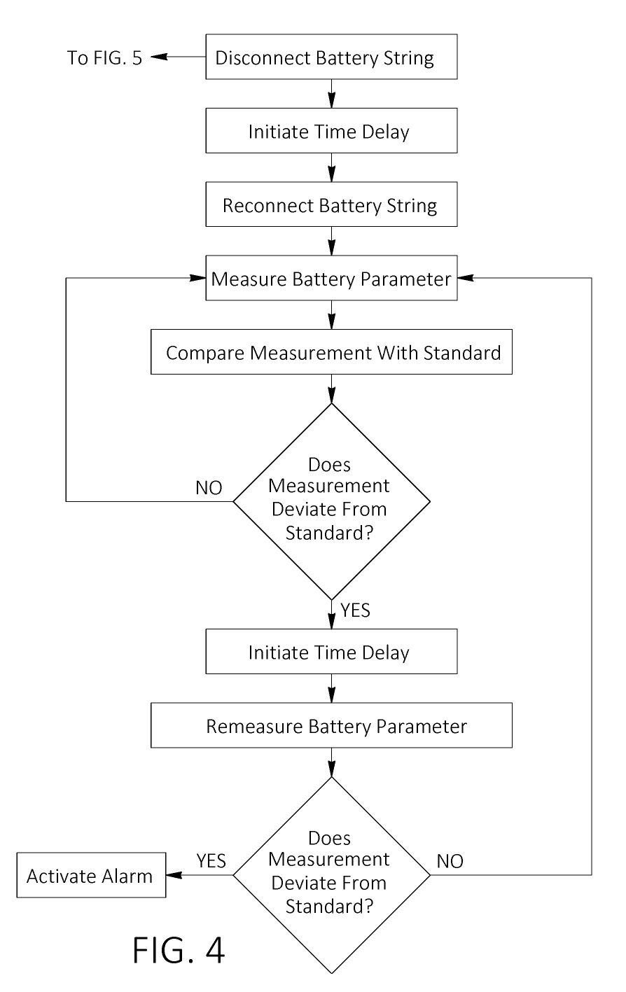

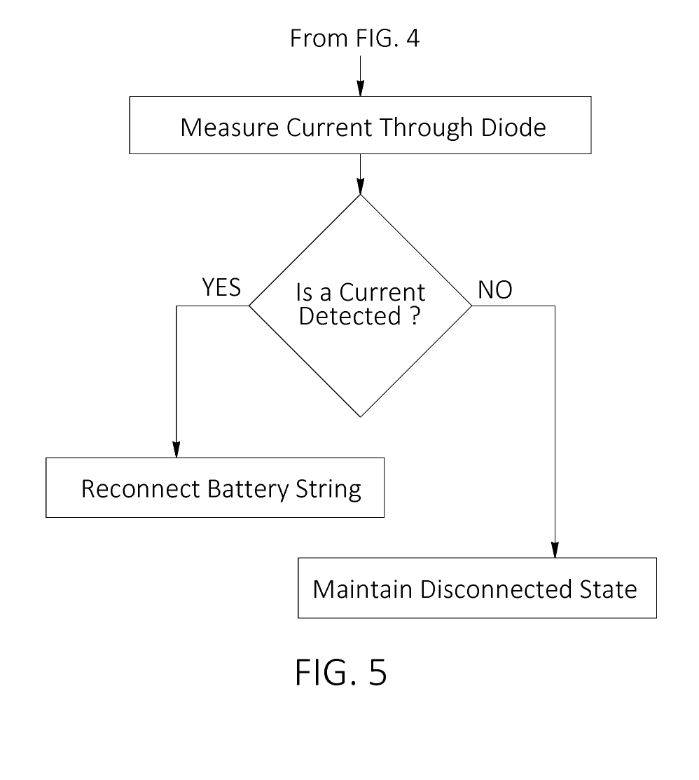

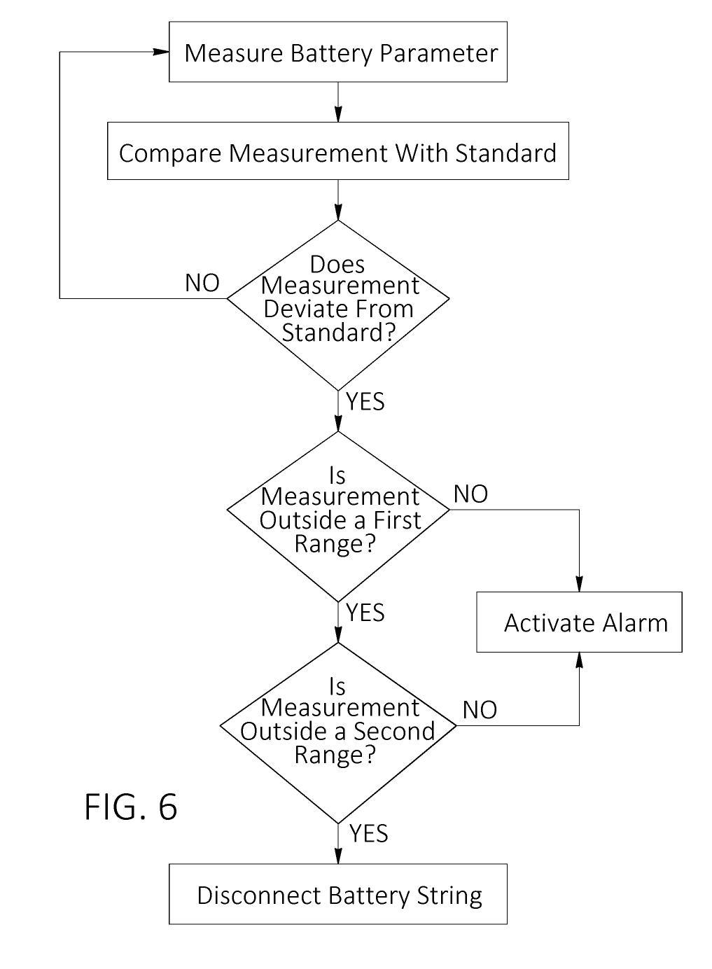

As seen in FIGS. 1-6, a thermal runaway detection and prevention system and method is shown. The present system dynamically compensates the float current set point for both temperature and voltage increases. Further, the present system may be set to delay a high float current alarm for a set period of time to determine whether the alarm is false or true. Additionally, when a high battery temperature alarm is activated, the battery can be disconnected without delay. The battery is disconnected from the AC charging input if a high temperature alarm is activated or if the preset time duration has been met for the high float current alarm. Moreover, when the battery is disconnected from the AC charging input, the battery remains connected to the critical load (such as the telecommunications system) through a diode, such that the battery can support the critical load when AC power to the charger fails. When the system experiences a power outage during an alarm condition, where the charging input has been disconnected, a current sensor detects the small current to the load through the diode, which is indicative of a power failure, and will quickly reset the contactor so that battery string is connected to the critical load through the contactor and not the diode arranged in parallel to the contactor.

FIG. 1 shows a preferred embodiment of the present battery monitoring system (20), with a battery string (22) and a second battery string (24) connected to the positive bus (50) through the system (20) and connected directly to the negative bus (52). Although two battery strings are shown, the present system can control a single string or multiple strings.

The battery string (22) is connected to the positive bus (50) through the charge inhibitor unit (46). The positive line leads from the positive terminal to the current sensor (32). The current sensor (32) detects a current through the contactor (36) and the diode (28), which are arranged in parallel. An ambient temperature sensor (26) is preferable located in the charge inhibitor unit (46); and a battery temperature probe (54) is located on or in close proximity to the battery string (22). Likewise, the second battery string (24) is connected to the positive bus (50) through the second inhibitor unit (48), with a second current sensor (34), a second diode (30), and a second contactor (38) arranged as in the charge inhibitor unit (46). The charge inhibitor unit (46) has a distribution module (40) to which various sensor line are connected from both units (46, 48), such as battery temperature (b, c) and current (a, d). A control module (42) houses various computing and data collection means that are used to compare measured values to standard values of battery parameters.

Looking at the poor float voltage alarm, most lead-acid battery manufacturers have specific recommendations for their batteries that the float voltage be raised or lowered according to the battery temperature difference from the nominal 77° F., acting as a temperature compensation. When considering a graph of the float voltage versus the battery temperature, the slope of the curve may be constant with battery temperatures above and below 77° F.; or the slope may vary for battery temperatures above 77° F. compared to battery temperatures below 77° F. The slope of this curve generally will be between 1.1-3.0 mV/° F., again depending on the battery. Further, battery manufacturers may have upper and lower battery temperature limits above and below which further temperature compensation is not recommended.

In one embodiment of the present system, the end-user may adjust set points to match manufacturer recommended settings. For example, for the GNB ABSOLYTE IIP VRLA battery, the temperature compensation slope above and below the nominal 77° F. can be set at (−3.00 mV/cell)/(° F.-77° F.), the maximum float voltage set at 2.35 V/cell, the minimum float voltage set at 2.21 V/cell, the float voltage at 77° F. is set at 2.25 V/cell, and the poor voltage alarm at 77° F. is set at 30 mV/cell error. First, the present system calculates the temperature compensated float voltage for a given measured battery temperature. Second, the present system compares the difference between the temperature compensated float voltage with the actual measured float voltage. Third, if that voltage difference exceeds the poor voltage alarm setting, then a time delay (such as 24 hours) is started, where the voltage difference is continuously or periodically measured. If the voltage difference is within the set parameters, then no time delay or alarm is activated. If the poor voltage condition persists for the duration of the time delay, then the poor voltage LED warning light is activated and the minor alarm relay is activated.

Next, looking at the high float current alarm, the float current is an exponential function of both float voltage and battery temperature. The float current will approximately double for a temperature increase of 15-18° F.; and the float current will also increase by a factor of up to ten times for a 0.1 V/cell increase of float voltage, from 2.25 V/cell to 2.35 V/cell. Thus, when determining the appropriate float current, compensation must be made for both the battery temperature and the float voltage. Further, since temperature and voltage continuously vary, the present system dynamically adjusts the float current set point throughout charging. If the measured float current is substantially different from the float current set point at a given point in time, then an alarm condition may be activated.

Continuing the system settings values for ABSOLYTE IIP battery example, if the battery temperature is 85° F. and a measured voltage of 2.27 V/cell, the nominal float current at 77° F. is set at 200 mA, the float current doubles for an increase of 15° F., the float current increases ten-fold per 100 mV/cell increase, the high float current #1 alarm set point is set for 10 times the final compensated float current set point, and the high float current #2 alarm set point is set for 20 times the T and V compensated float current set point.

First, the float current set point is compensated for voltage:

$$V Compensated Float Current = ( Nominal Float Current a t 77 ° F . ) {( 2 )}^{( \begin{matrix}Measured V - \\ Float V at 77 degrees F\end{matrix} ) / ( poor voltage alarm )} = ( 200 mA ) {( 2 )}^{( 2.27 V - 2.25 V ) / ( 0.03 V )} = 317.5 mA$$

Second, the float current set point is compensated for temperature and voltage:

$$\begin{matrix} \begin{matrix}T and V Compensated \\ Float Current\end{matrix} = \begin{matrix}( V Compensated Float Current ) \\ {( 2 )}^{( \begin{matrix}Measured T - \\ Nominal T\end{matrix} ) / ( 15 degrees F )}\end{matrix} \\ {= ( 317.5 mA ) ( 2 ) )}^{( \begin{matrix}85 degrees F - \\ 77 degrees F\end{matrix} ) / ( 15 degrees F )} \\ = 459.5 mA\end{matrix}$$

Thus, the temperature and voltage compensated float current would be set at 459.5 mA for a given moment at the above parameters, which changes dynamically with changes in float voltage and battery temperature. Next, the actual float current is periodically measured and compared to the T and V compensated float current, if the measured float current exceed a value that is 10 times the T and V compensated float current (4595 mA in this example), then a time delay begins and if the alarm condition persists throughout this period, the minor alarm relay (alarm #1) is activated. Also, if the if the measured float current exceed a value that is 20 times the T and V compensated float current (9190 mA in this example), a time delay begins and if the alarm condition persists throughout this period, then the major alarm relay (alarm #2) is activated. Once the major alarm relay is activated, the contactor is opened, which disconnects the charging input from the battery. After a set time delay (8 hours for example), the contactor is closed and the battery is reconnected to the charging input.

Because of the danger of fire and severe damage, when the high battery temperature alarm is activated, it immediately opens the contactor to disconnect the charging input from the battery. The contactor remains open until the measured battery temperature decreases to an acceptable level, by 10° F. in this example. This is an important feature for bulk charging the battery after a deep discharge event, where the battery must be charged at a level exceeding the float charge level. The high current level during the bulk charge may drive a battery into thermal runaway. Thus, when the battery temperature exceeds the defined safe limit, then the contactor is opened, only closing upon an appropriate decrease in battery temperature. Thus, the bulk charging process can continue without undue delay. The process of bulk charging, cooling down, and reinstating the bulk charging process may be repeated until the appropriate rest state voltage has been achieved. Usually when there is a deep discharge event caused by a prolonged power outage, the air conditioning unit in the building has been inactive. Thus, the ambient temperature will remain at an elevated level for a period of time after AC power is restored. The batteries are especially vulnerable to thermal runaway with the elevated ambient temperature and the simultaneous bulk charging.

The contactor and diode are arranged in parallel, so that under normal circumstance, where there is no thermal runaway disconnect event and there is a power outage, then the battery is already connected to the critical load through the contactor. If, however, the contactor is open due to an alarm condition and there is a power outage, the battery string is still connected to the critical load through the diode. When the system experiences a power outage during a major alarm condition, where the charging input has been disconnected, a current sensor detects the current to the load through the diode, which is indicative of a battery discharge, and will immediately reset the contactor so that battery string is connected to the critical load through the contactor and not the diode arranged in parallel to the contactor. The float current level will be very low (1-2 A). In order to measure these low levels of current and to measure current of the batteries in normal conditions, a temperature compensated Hall Effect sensor in a gapped toroid arrangement is used. The current sensor can be calibrated to provide an accuracy of 2% of reading from 100 mA to 10 A. The calibration will be compensated for the actual sensor spacing of the conductor through which the current passes.

The advantages of the diode only temporarily connecting the battery to the critical load during a power outage and thermal runaway alarm event, is that the voltage drop across the diode is eliminated and expensive and large heat sinks are not required. Thus, the diode and heat sink system can be sized for short term duty rather than continuous duty.

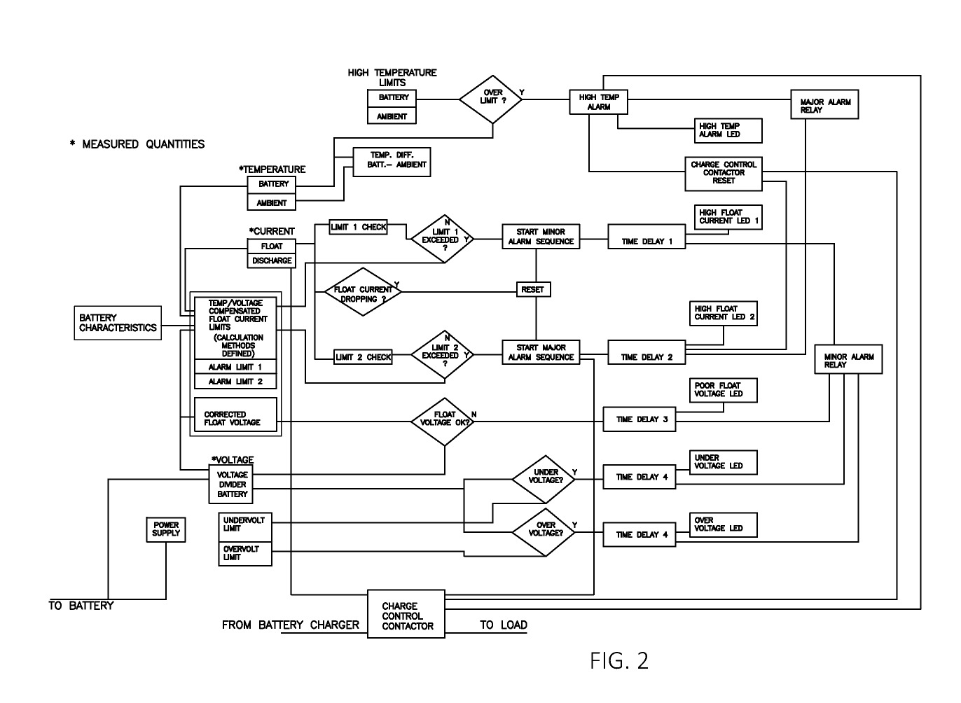

As can be seen in FIG. 2, the present system can control multiple strings of batteries, two strings in this case. Each string has a dedicated charge inhibitor unit, with a dedicated contactor and diode. In this way, if a first battery string is experiencing a thermal runaway event, the remaining healthy strings can remain connected to the critical load through the contactor, while the first string is disconnected or is under an alarm time delay.

While particular forms of the invention have been illustrated and described, it will also be apparent to those skilled in the art that various modifications can be made without departing from the spirit and scope of the invention. Accordingly, it is not intended that the invention be limited except by the claims.

What is claimed is:

1. A method to monitor and control a battery string charged by a charging source and connected to a critical load, the method comprising the steps of:
measuring a battery parameter with a sensor to collect a measurement indicative of a condition of the battery string;
comparing the measurement with a standard battery parameter;
determining whether the measurement deviates outside a set range from the standard battery parameter;
initiating a time delay if the measurement deviates outside the set range from the standard battery parameter;
remeasuring the battery parameter at least once during the time delay to collect an additional measurement; and
activating an alarm if the additional measurement deviates outside the set range from the standard battery parameter.

2. The method of claim 1, wherein the step of measuring the battery parameter includes:
measuring a float voltage; and
the step of comparing the measurement with the standard battery parameter includes:
comparing the float voltage with a standard float voltage compensated for a measured battery temperature.

3. The method of claim 1, wherein the step of measuring the battery parameter includes:
measuring a float current; and
the step of comparing the measurement with the standard battery parameter includes:
comparing the float current with a standard float current compensated for a measured battery temperature and compensated for a measured float voltage.

4. The method of claim 1, wherein the step of activating the alarm includes:
activating a perceptible alarm.

5. The method of claim 1, wherein the step of activating the alarm includes:
disconnecting the battery string from the charging source.

6. The method of claim 5 further comprising the steps of:
initiating a disconnect time delay after disconnecting the battery string; and
reconnecting the battery string to the charging source after expiration of the disconnect time delay.

7. The method of claim 6 further comprising the steps of:
measuring the battery parameter after reconnecting the battery string to the charging source to collect a verification measurement;
comparing the verification measurement with the standard battery parameter;
determining whether the verification measurement deviates outside the set range from the standard battery parameter;
initiating a second time delay if the measurement deviates outside the set range from the standard battery parameter;
remeasuring the battery parameter at least once during the second time delay to collect a further additional measurement; and
activating the alarm if the further additional measurement deviates outside the set range from the standard battery parameter.

8. The method of claim 5 further comprising the steps of:
disconnecting the battery string from a charging source by opening a contactor arranged in parallel with a diode, wherein the battery string is normally connected to the charging source through the contactor and the diode;
measuring a current through the diode;
maintaining the contactor in the open position if the current is not detected through the diode; and
closing the contactor if the current is detected through the diode.

9. The method of claim 1, wherein the step of determining whether the measurement deviates outside the set range from the standard battery parameter includes:
determining whether the measurement deviates outside a first set range from the standard battery parameter; and
determining whether the measurement deviates outside a second set range from the standard battery parameter, wherein the second set range is greater than the first set range.

10. The method of claim 9, wherein the step of activating the alarm if the additional measurement deviates outside the set range from the standard battery parameter includes:
producing a perceptible alarm if the measurement deviates outside the first set range and is within the second set range; and
disconnecting the battery string from a charging source if the measurement deviates outside the second set range.

11. The method of claim 1, wherein the step of measuring the battery parameter includes:
measuring a hydrogen level; and
the step of comparing the measurement with the standard battery parameter includes:
comparing the hydrogen level with a maximum hydrogen level.

12. The method of claim 1, wherein the step of measuring the battery parameter with the sensor includes:
measuring the battery parameter with a smoke detection device.

13. The method of claim 12, wherein the step of measuring the battery parameter includes:
measuring a smoke particulate level with the smoke detection device; and
the step of comparing the measurement with the standard battery parameter includes:
comparing the smoke particulate level with a maximum smoke particulate level, wherein the maximum heat level is deemed exceeded when the smoke detection device activates.

14. The method of claim 1, wherein the step of measuring the battery parameter with the sensor includes:
measuring the battery parameter with a heat detection device.

15. The method of claim 14, wherein the step of measuring the battery parameter includes:
measuring a heat level with the heat detection device; and
the step of comparing the measurement with the standard battery parameter includes:
comparing the heat level with a maximum heat level, wherein the maximum heat level is deemed exceeded when the heat detection device activates.
